(19) United States
(12) Patent Application Publication
(10) Pub. No.: US 2008/0315280 A1
(43) Pub. Date: Dec. 25, 2008

(54) SEMICONDUCTOR MEMORY DEVICE HAVING MEMORY CELL UNIT AND MANUFACTURING METHOD THEREOF

(76) Inventors: Shinichi WATANABE, Yokohama-shi (JP); Fumitaka Arai, Yokohama-shi (JP); Makoto Mizukami, Kawasaki-shi (JP); Hirofumi Inoue, Kamakura-shi (JP); Masaki Kondo, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/142,274

(22) Filed: Jun. 19, 2008

(30) Foreign Application Priority Data
Jun. 22, 2007 (JP) 2007-165365

(51) Int. Cl. H01L 29/423; H01L 21/336

(52) U.S. Cl. 257/315; 438/258; 257/E29.129

(57) ABSTRACT

A semiconductor memory device includes a silicon substrate including a first region which has a buried insulating layer below a single-crystal silicon layer and a second region which does not have the buried insulating layer below the single-crystal silicon layer, at least one memory cell transistor which has a first gate electrode, the first gate electrode being provided on the single-crystal silicon layer in the first region, and at least one selective gate transistor which has a second gate electrode and is provided on the single-crystal silicon layer in the first region. The one selective gate transistor is provided in such a manner that a part of the second gate electrode is placed on the single-crystal silicon layer in the second region.

### CROSS-REFERENCE TO RELATED APPLICATIONS

This application is based upon and claims the benefit of priority from prior Japanese Patent Application No. 2007-165365, filed Jun. 22, 2007, the entire contents of which are incorporated herein by reference.

### BACKGROUND OF THE INVENTION

1. Field of the Invention

The present invention relates to a semiconductor memory device and a manufacturing method thereof. More particularly, the present invention relates to a semiconductor memory device having a memory cell unit and a manufacturing method thereof.

2. Description of the Related Art

As a nonvolatile semiconductor memory device in which information can be electrically rewritten and which can be highly integrated, a NAND flash electrically erasable programmable read-only memory (EEPROM) is known. A memory cell transistor of the NAND flash EEPROM has a laminated gate structure. The laminated gate structure has a tunnel insulating film, a floating gate electrode layer intended to store electric charges, an inter-electrode insulating film, and a control gate electrode layer laminated on a substrate.

In the NAND flash EEPROM, a memory cell transistor is arranged at each intersection of a word line in a row direction and a bit line in a column direction. Further, a predetermined number of memory cell transistors are connected in series to constitute one NAND cell unit.

In recent years, miniaturization and integration of a semiconductor memory device have advanced, and an area per memory cell transistor has been reduced. With this miniaturization of a memory cell size, an influence of a parasitic capacitance in an element isolating region or a parasitic capacitance between an interconnect and the substrate is increased, and hence a problem that threshold voltages of the memory cell transistors become non-uniform prominently arises.

To reduce non-uniformity of the threshold voltages involved by miniaturization of the memory cell transistors, applying silicon-on-insulator (SOI) technology to a NAND flash EEPROM has been examined. In SOI technology, an SOI wafer is used. The SOI wafer includes a buried oxide film layer provided on a substrate and a single-crystal silicon layer provided on this buried oxide film layer. Furthermore, a semiconductor device is formed in this single-crystal silicon layer. In a NAND flash EEPROM utilizing SOI technology, since memory cell transistors adjacent to each other along a row direction are electrically isolated by the buried oxide film layer, thereby reducing a parasitic capacitance in an element isolating region. Moreover, since the buried oxide film layer can be used to reduce a parasitic capacitance between an interconnect and the substrate, non-uniformity of the threshold voltages of the memory cell transistors can be suppressed. Additionally, using SOI technology enables suppressing a problem caused due to a short channel effect involved by miniaturization of the semiconductor memory device.

It is to be noted that the single-crystal silicon layer requires a good-quality single crystal layer in terms of reliability. Therefore, an SOI substrate (a laminated structure of the substrate, the buried oxide film layer, and the single-crystal silicon layer) is generally fabricated based on, e.g., separation by implanted oxygen (SIMOX) or a Smartcut process involving high cost. Thus, a method of fabricating an inexpensive and good-quality single crystal silicon layer is demanded.

Further, the following matters must be also considered when manufacturing the semiconductor memory device. The semiconductor memory device generally has a memory cell unit and a peripheral circuit unit. Memory cell transistors are formed in the memory cell unit, and peripheral circuits required for operations of the memory cell transistors are formed in the peripheral circuit unit. However, a process required to form the memory cell unit is different from a process required to form the peripheral circuit unit because of, e.g., a difference between characteristics required for the memory cell transistors and the peripheral circuits. To manufacture the semiconductor memory device at a fewer number of manufacturing steps, increasing the number of manufacturing steps used for formation of the memory cell unit and formation of the peripheral circuit unit in common is demanded. That is, a manufacturing process enabling forming both the memory cell unit and the peripheral circuit unit at a fewer number of manufacturing steps is desirable.

As prior art document information concerning the invention of this application, see, for example, Jpn. Pat. Appln. KOKAI Publication No. 11-163303 or see, for example, Jpn. Pat. Appln. KOKAI Publication No. 2006-073939.

### BRIEF SUMMARY OF THE INVENTION

According to a first aspect of the present invention, there is provided a semiconductor memory device comprising:

a silicon substrate including a first region which has a buried insulating layer below a single-crystal silicon layer and a second region which does not have the buried insulating layer below the single-crystal silicon layer;

at least one memory cell transistor which has a first gate electrode, the first gate electrode being provided on the single-crystal silicon layer in the first region; and

at least one selective gate transistor which has a second gate electrode, the second gate electrode being provided to be partially placed on the single-crystal silicon layer in the second region.

According to a second aspect of the present invention, there is provided a semiconductor memory device comprising:

a silicon substrate including a first region which has a buried insulating layer below a single-crystal silicon layer and a second region which is adjacent to the first region and does not have the buried insulating layer below the single-crystal silicon layer;

at least one memory cell transistor having a first gate electrode formed on the single-crystal silicon layer in the first region;

one selective gate transistor having a second gate electrode which is adjacent to the one memory cell transistor and formed on the single-crystal silicon layer to span the first region and the second region; and

one contact plug which is adjacent to the one selective gate transistor and formed on the single-crystal silicon layer in the second region,

wherein the one contact plug and the second gate electrode are connected with each other through a first diffusion layer which is formed in the single-crystal silicon layer in the second region, is of a first conductivity type, and has a first concentration,

the first gate electrode and the second gate electrode are connected with each other through a second diffusion layer which is formed in the single-crystal silicon layer in the first region, is of the same conductivity type as the first conductivity type, and has a second concentration higher than the first concentration, and

an impurity region which is of the same conductivity type as the first conductivity type and has a third concentration lower than the first concentration is formed in the single-crystal silicon layer in the first region below the first gate electrode excluding the second diffusion layer.

According to a third aspect of the present invention, there is provided a manufacturing method of a semiconductor memory device having a memory cell unit, comprising:

forming an insulating layer on a silicon substrate, the insulating layer having an opening from which a part of a surface of the silicon substrate associated with the memory cell unit is exposed;

forming a semiconductor layer on the surface of the silicon substrate in the opening and on the insulating layer;

forming a first impurity region which is of a first conductivity type in a first region of the semiconductor layer associated with the insulating layer;

forming a first impurity region which is of a second conductivity type in a second region of the semiconductor layer associated with the opening;

forming at least one first gate structure which is associated with the first region and has a first insulating film, a first electrode, a second insulating film, and a second electrode laminated on the semiconductor layer and one second gate electrode which has a third insulating film and a third electrode laminated on the semiconductor layer to span the first region and the second region;

forming a second impurity region which is of the first conductivity type in a surface portion of the semiconductor layer associated with the second region to be adjacent to the one second gate structure; and

forming a third impurity region which is of the first conductivity type in a surface portion of the semiconductor layer associated with the first region to be adjacent to the one first gate structure.

### BRIEF DESCRIPTION OF THE SEVERAL VIEWS OF THE DRAWING

FIG. 1 is a plan view showing a structural example of a semiconductor memory device (a NAND flash memory device) according to a first embodiment of the present invention;

FIGS. 2A and 2B are cross-sectional views showing a structural example of the semiconductor memory device according to the first embodiment;

FIGS. 3A and 3B are cross-sectional views for explaining a manufacturing step of the semiconductor memory device according to the first embodiment;

FIGS. 4A and 4B are cross-sectional views for explaining a manufacturing step of the semiconductor memory device according to the first embodiment;

FIGS. 5A and 5B are cross-sectional views for explaining a manufacturing step of the semiconductor memory device according to the first embodiment;

FIGS. 6A and 6B are cross-sectional views for explaining a manufacturing step of the semiconductor memory device according to the first embodiment;

FIGS. 7A and 7B are cross-sectional views for explaining a manufacturing step of the semiconductor memory device according to the first embodiment;

FIGS. 8A and 8B are cross-sectional views for explaining a manufacturing step of the semiconductor memory device according to the first embodiment;

FIGS. 9A and 9B are cross-sectional views for explaining a manufacturing step of the semiconductor memory device according to the first embodiment;

FIGS. 10A and 10B are cross-sectional views for explaining a manufacturing step of the semiconductor memory device according to the first embodiment;

FIGS. 11A and 11B are cross-sectional views for explaining a manufacturing step of the semiconductor memory device according to the first embodiment; and

FIGS. 12A and 12B are cross-sectional views for explaining a manufacturing step of the semiconductor memory device according to the first embodiment.

### DETAILED DESCRIPTION OF THE INVENTION

Embodiments of the present invention will be described with reference to the accompanying drawings. It should be noted that the drawings are schematic ones and the dimension ratios shown therein are different from the actual ones. The dimensions vary from drawing to drawing and so do the ratios of dimensions. The following embodiments are directed to a device and a method for embodying the technical concept of the present invention and the technical concept does not specify the material, shape, structure or configuration of components of the present invention. Various changes and modifications can be made to the technical concept without departing from the scope of the claimed invention.

### First Embodiment

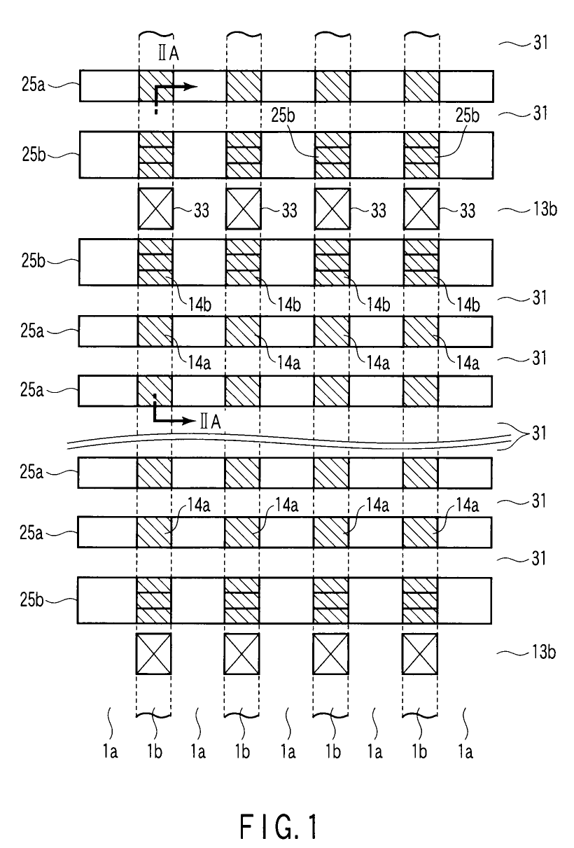

A semiconductor memory device according to a first embodiment of the present invention will now be explained with reference to FIG. 1 to FIGS. 12A and 12B.

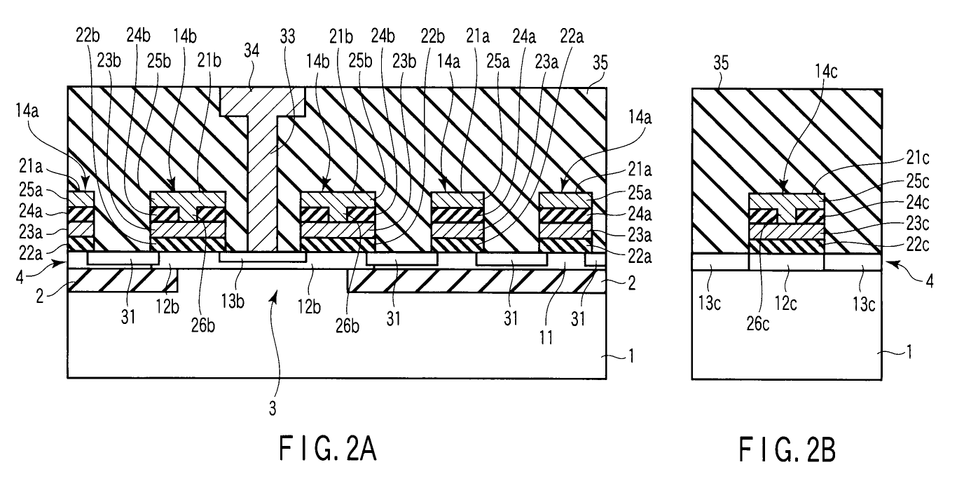

FIG. 1 and FIGS. 2A and 2B show a structural example of a NAND flash memory device (a NAND flash EEPROM) as a semiconductor memory device. It is to be noted that FIG. 1 is a plan view showing a primary part of a memory cell unit. FIG. 2A is a cross-sectional view showing a structure of a portion taken along a line IIA-IIA in FIG. 1, and FIG. 2B is a cross-sectional view showing a primary part of a peripheral circuit unit (a peripheral transistor).

As shown in FIG. 1 and FIGS. 2A and 2B, in the memory cell unit of the NAND flash memory device according to this embodiment, a buried insulating layer 2 formed of a silicon oxide film is provided on a silicon substrate 1 formed of p-type single crystal silicon as a semiconductor substrate. The buried insulating layer 2 partially has an opening (a region where the silicon oxide film is removed) reaching the silicon substrate 1.

An n-type single crystal silicon layer 4 is provided on the buried insulating layer 2. As will be explained later, the single-crystal silicon layer 4 is formed based on growth utilizing the silicon substrate 1 exposed in the opening 3 as a seed.

Here, a region where the buried insulating layer 2 is provided between the single-crystal silicon layer 4 and the silicon substrate 1 will be referred to as an SOI region (a first region), and a region formed of the single-crystal silicon layer 4 and the silicon substrate 1 without having the buried insulating layer 2 will be referred to as a non-SOI region (a second region).

In the memory cell unit, a plurality of memory cell transistors 14a and a plurality of selective gate transistors 14b are provided on the single-crystal silicon layer 4. Further, a peripheral transistor 14c is provided on the single-crystal silicon layer 4 in the peripheral circuit unit. The plurality of memory cell transistors 14a are provided in the SOI region, respectively. Furthermore, each of the plurality of selective gate transistors 14b is provided on a boundary region (an edge region of the opening 3) between the SOI region and the non-SOI region to span each region. That is, for example, as shown in FIG. 2A, each of the plurality of selective gate transistors 14b is provided in accordance with each boundary region between an SOI/non-SOI pair.

An n⁻-type diffusion layer 11 containing an n-type impurity at a low concentration is formed in the entire surface of the single-crystal silicon layer 4 below the region where the memory cell transistors 14a of the memory cell unit are formed. This n⁻-type diffusion layer 11 is formed over the entire region of single-crystal silicon layer 4 in a thickness direction from an upper surface to a lower surface of the single-crystal silicon layer 4. A p-type well 12b is formed in the single-crystal silicon layer 4 below a gate electrode of each selective gate transistor 14b of the memory cell unit. On the other hand, for example, as shown in FIG. 2B, a p-type well 12c is formed in the single-crystal silicon layer 4 below a gate electrode of the peripheral transistor 14c of the peripheral circuit unit. The p-type wells 12b and 12c are formed over the entire region of the single-crystal silicon layer 4 in the thickness direction from the upper surface to the lower surface of the single-crystal silicon layer 4. It is to be noted that the p-type wells 12b and 12c may reach the silicon substrate 1 below the single-crystal silicon layer 4.

An n-type diffusion layer 13b is formed in the p-type well 12b in the non-SOI region of the single-crystal silicon layer 4. The n-type diffusion layer 13b is formed in the single-crystal silicon layer 4 at a position corresponding to a space between the two selective gate transistors 14b adjacent to each other. Moreover, in the peripheral circuit unit, n-type diffusion layers 13 are formed in the single-crystal silicon layer 4 to sandwich a region (the p-type well 12c) below the gate electrode of the peripheral transistor 14c. Each of the n-type diffusion layers 13b and 13c has an n-type impurity with a higher concentration than the n⁻-type diffusion layer 11. Each of the n-type diffusion layers 13b and 13c has a function as a source/drain region of the selective gate transistor 14b or the peripheral transistor 14c.

The memory cell transistor 14a is formed of a laminated-gate-structure metal oxide semiconductor field-effect transistor (MOSFET). A laminated gate structure 21a as a gate electrode of the memory cell transistor 14a includes at least a tunnel insulating film 22a formed on the single-crystal silicon layer 4, a floating gate electrode 23a formed on the tunnel insulating film 22a, an inter-electrode insulating film 24a formed on the floating gate electrode 23a, and a control gate electrode 25a formed on the inter-electrode insulating film 24a.

In this manner, the memory cell transistor 14a is placed above the buried insulating layer 2. Therefore, a problem of the memory cell transistor 14a concerning a parasitic capacitance can be avoided by an effect obtained from SOI technology. It is to be noted that the memory cell transistor 14a is formed as a depletion type. That is, in a state where electrons are not stored in the floating gate electrode 23a (binary 1), a threshold voltage of the memory cell transistor 14a has a negative value. On the other hand, in a state where electrons are stored in the floating gate electrode 23a (binary 0), the threshold voltage of the memory cell transistor 14a has a positive value. In a read operation, when the memory cell transistor 14a holds binary 1, the memory cell transistor 14a is on. In the case of binary 0, a depletion layer expands in a channel region immediately below the gate, and the memory cell transistor 14a is off without having a channel current flowing therethrough. That is, it is determined that the held data is binary 1 when the channel current flows, and that the held data is binary 0 when the channel current does not flow.

The selective gate transistor 14b is formed of a laminated gate structure MOSFET. A laminated gate structure 21b as a gate electrode of the selective gate transistor 14b includes at least a gate insulating film 22b formed on the single-crystal silicon layer 4, a lower gate electrode 23b formed on the gate insulating film 22b, an inter-electrode insulating film 24b formed on the lower gate electrode 23b, and an upper gate electrode 25b formed on the inter-electrode insulating film 24b.

As shown in FIG. 2A, the laminated gate structure 21b of the selective gate transistor 14b is provided in such a manner that a part of it is in contact with the non-SOI region and the remaining part is in contact with the SOI region. Therefore, the laminated gate structure 21b of the selective gate transistor 14b has the same state as that where it is formed on a bulk silicon substrate. Therefore, the selective gate transistor 14b is formed as an enhancement type.

As shown in FIG. 2B, the peripheral transistor 14c is formed of a laminated gate structure MOSFET. A laminated gate structure 21c of the peripheral transistor 14c includes at least a gate insulating film 22c formed on the single-crystal silicon layer 4, a lower gate electrode 23c formed on the gate insulating film 22c, an inter-electrode insulating film 24c formed on the lower gate insulating film 23c, and an upper control gate electrode 25c formed on the inter-electrode insulating film 24c. The peripheral transistor 14c is formed on the single-crystal silicon layer 4 after completely removing the buried insulating layer 2 in the peripheral circuit unit. That is, this is equivalent to forming the peripheral transistor 14c on a bulk substrate, and the peripheral transistor 14c is formed as the enhancement type.

Openings 26b and 26c reaching a lower surface from an upper surface are formed in the inter-electrode insulating films 24b and 24c, respectively. The upper gate electrodes 25b and 25c are partially buried in these openings 26b and 26c, respectively. As a result, the lower gate electrodes 23b and 23c are integrated with the upper gate electrodes 25b and 25c to constitute gate electrodes of the transistors, respectively.

In FIG. 2A, an n⁺-type diffusion layer 31 is formed between the respective laminated gate structures 21a of the memory cell transistors 14a or between the laminated gate structure 21a and the laminated gate structure 21b of the selective gate transistor 14b in the single-crystal silicon layer 4. Each of the n⁺-type diffusion layers 31 contains an n-type impurity with a higher concentration than the n⁻-type diffusion layer 11, and these layers 31 are all formed in the single-crystal silicon layer 4 above the buried insulating layer 2. Moreover, the n⁺-type diffusion layer 31 is formed in a shallow region of the single-crystal silicon layer 4 alone, and does not reach the buried insulating layer 2. The n⁺-type diffusion layer 31 has a function as a source/drain region of the memory cell transistor 14a and the selective gate transistor 14b.

An impurity that controls a threshold voltage is introduced in a channel region below each laminated gate structure 21a of the memory cell transistor 14a. A concentration of this impurity is set high in the single-crystal silicon layer 4 on the laminated gate structure 21a side and set low in the same on the buried insulating layer 2 side.

It is to be noted that an interlayer insulating film 35 is provided on the respective laminated gate structures 21a, 21b, and 21c.

As shown in FIG. 1, a plurality of element isolating regions 1a are formed on a surface of the silicon substrate 1 along a column direction (the vertical direction in the drawing) at predetermined intervals. These element isolating regions 1a form a plurality of element regions 1b extending in the column direction at predetermined intervals. The single-crystal silicon layer 4 depicted in FIG. 2A is formed on each element region 1b. The plurality of control gate electrodes 25a of the memory cell transistors 14a as word lines are extended in a row direction (the lateral direction in the drawing) to span the plurality of element regions 1b at predetermined intervals, respectively. Additionally, the memory cell transistor 14a is provided at each intersection of the control gate electrode 25a and the element region 1b. Further, the upper gate electrodes 25b of the selective gate transistors 14b as selective gate lines are also provided in the row direction in parallel with the control gate electrodes 25a. The selective gate transistor 14b is provided at each intersection of the upper gate electrode 25b and the element region 1b. In the row direction, the respective control gate electrodes 25a of the memory cell transistors 14a adjacent to each other (belonging to the same row) are connected with each other. Likewise, in the column direction, the upper gate electrodes 25b of the selective gate transistors 14b adjacent to each other (belonging to the same column) are connected with each other.

A predetermined number of memory cell transistors 14a which are adjacent to each other in the column direction are connected in series to share the n⁺-type diffusion layers 31, and one end of each selective gate transistor 14b is connected with each of both ends of a group of the series-connected memory cell transistors 14a (a NAND cell unit) through the n⁺-type diffusion layer 31. The other end of each selective gate transistor 14b is connected with a contact plug 33 through the n-type diffusion layer 13b. This contact plug 33 is connected with an interconnect 34 serving as a bit line or a source line.

According to this embodiment, when the n⁺-type diffusion layer 31 is formed, a larger current can be flowed through the memory cell transistor 14a without forming the n⁺-type diffusion layer as compared with a case where the n-type diffusion layer is used as the source/drain region. Therefore, a large cell current can be assured. Furthermore, paying attention to a given memory cell transistor 14a, forming the n⁺-type diffusion layer 31 enables suppressing (shielding) an influence of an electric field from the floating gate electrode 23a of the memory cell transistor 14a adjacent to this memory cell transistor 14a. As a result, the read margin can be improved.

Moreover, an impurity that is used to control the threshold voltage is introduced in the channel region of each memory cell transistor 14a (the n⁻-type diffusion layer 11). Since a concentration of this impurity is set high in the single-crystal silicon layer 4 on the laminated gate structure 21a side, controllability of each memory cell transistor 14a is improved, thereby facilitating injection of electrons into each floating gate electrode 23a. Additionally, since the impurity concentration in the channel region on the buried insulating layer 2 side is set lower than that on the laminated gate structure 21a side, a deletion layer can be readily expanded. That is, in the channel region, giving a gradient of the impurity concentration so that the concentration is lowered along the depth direction of the single-crystal silicon layer 4 enables improving cutoff characteristics of each memory cell transistor 14a.

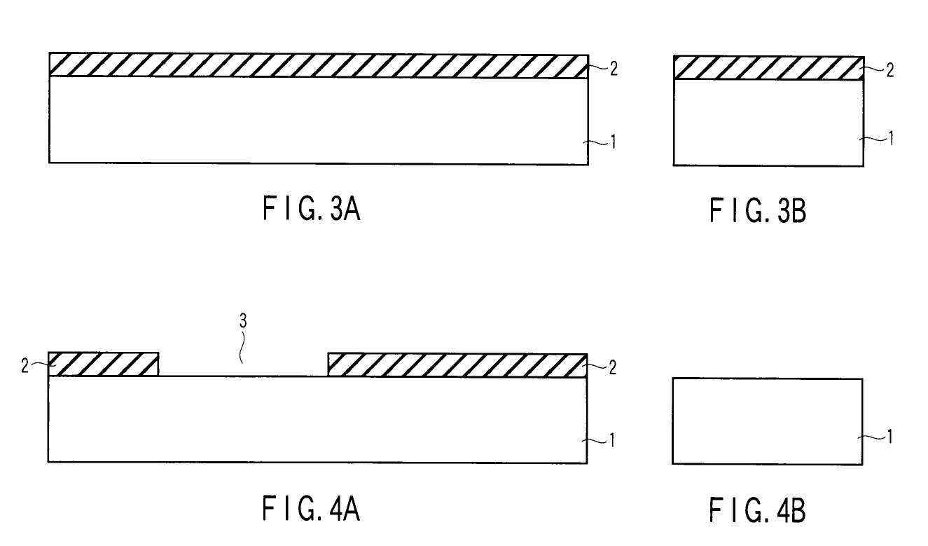

A manufacturing method of the semiconductor memory device depicted in FIG. 1 and FIGS. 2A and 2B will now be explained with reference to FIGS. 3A and 3B to FIGS. 12A and 12B. It is to be noted that FIGS. 3A to 12A show cross sections corresponding to FIG. 2A in order of manufacturing steps. Likewise, FIGS. 3B to 12B show cross sections corresponding to FIG. 2B in order of manufacturing steps.

First, as shown in FIGS. 3A and 3B, oxidizing a front surface of the silicon substrate 1 formed of single-crystal silicon enables forming the buried insulating layer 2 on the front surface of the silicon substrate 1.

Then, as shown in FIGS. 4A and 4B, a mask material (not shown) is formed on the buried insulating layer 2 by using, e.g., chemical vapor deposition (CVD). Subsequently, a pattern having an opening above a region where the opening 3 is to be provided is formed in the mask material by using a lithography process and anisotropic etching such as reactive ion etching (RIE). Then, the mask material is used as a mask to form the opening 3 based on, e.g., RIE. Subsequently, the mask material is removed. The opening 3 is placed in a region where the selective gate transistor 14b and the contact plug 33 for a bit line contact are to be formed. Moreover, a part of the buried insulating layer 2 in a region where at least a peripheral transistor of the peripheral circuit unit is to be formed is removed.

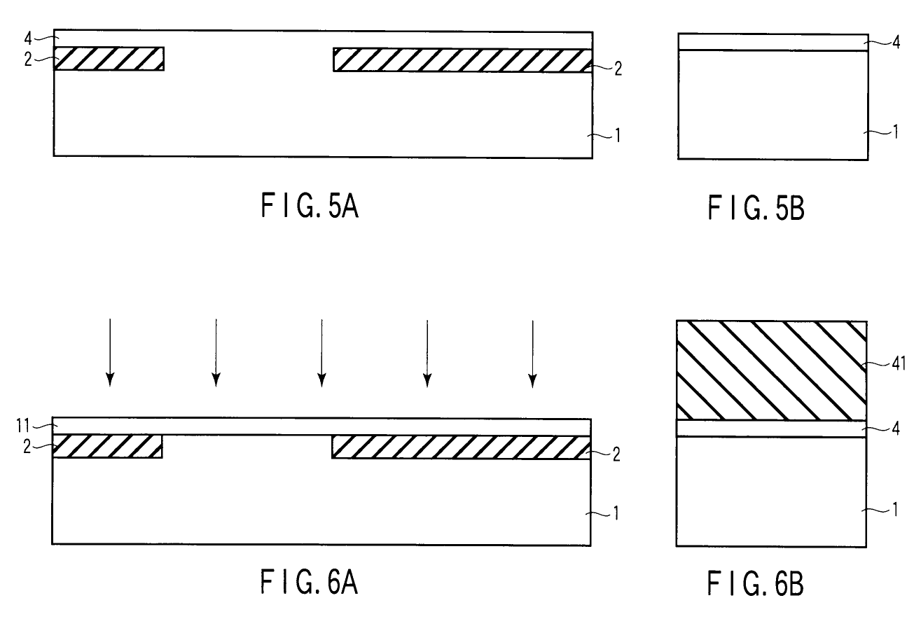

Then, as shown in FIGS. 5A and 5B, the silicon substrate exposed in the opening 3 and the silicon substrate 1 exposed in the peripheral circuit unit are used as seeds to grow amorphous silicon or polysilicon so that the buried insulating layer 2 is entirely covered. Further, when this silicon is annealed, the single-crystal silicon layer 4 having excellent crystallinity can be formed. When the single-crystal silicon layer 4 is formed by such a method, an SOI substrate (a laminated structure of the substrate, the buried insulating layer, and the single-crystal silicon layer) can be fabricated as a lower cost than that in general SIMOX or a Smartcut process.

Subsequently, as shown in FIGS. 6A and 6B, a mask material 41 that covers the peripheral circuit unit is formed based on, e.g., CVD, lithography, or RIE. Then, the n⁻-type diffusion layer 11 is formed in the single-crystal silicon layer 4 of the memory cell unit based on ion implantation using the mask material 41 as a mask. Subsequently, the mask material 41 is removed.

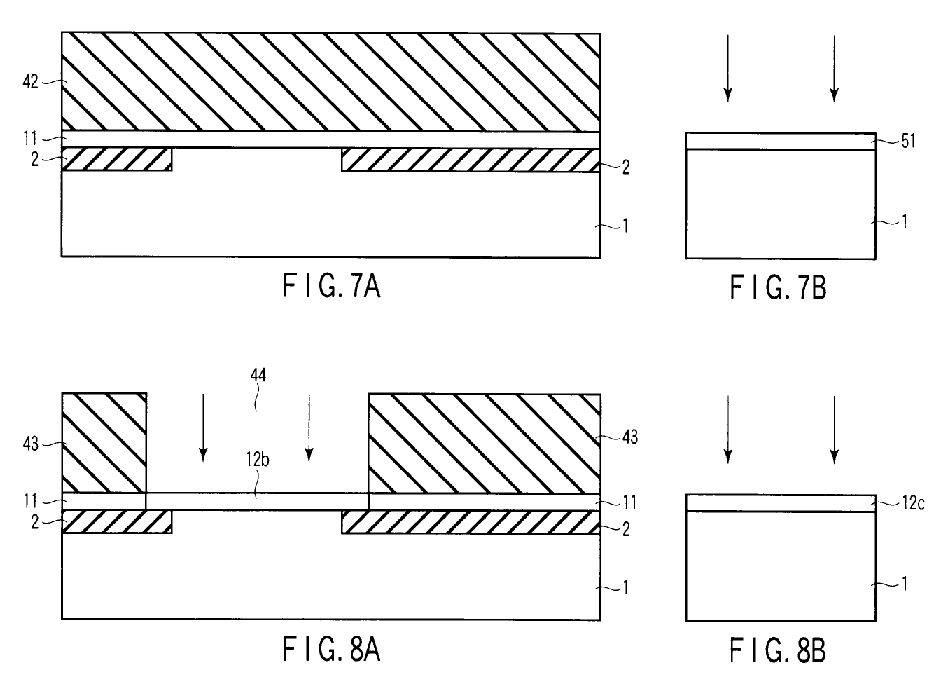

Then, as shown in FIGS. 7A and 7B, a mask material 42 that covers the memory cell unit is formed based on, e.g., CVD, the lithography process, or RIE. Subsequently, a p-type well 51 is formed in the single-crystal silicon layer 4 of the peripheral circuit unit based on ion implantation using the mask material 42 as a mask. Then, the mask material 42 is removed.

Then, as shown in FIGS. 8A and 8B, a mask material 43 having an opening 44 is formed to cover the memory cell unit based on, e.g., CVD, the lithography process, or RIE. The opening 44 is associated with the region where the selective gate transistor 14b and the contact plug 33 are to be formed. More particularly, the opening 44 is placed in a region including at least the region where the laminated gate structure 21b is to be formed. Subsequently, the p-type well 12b is formed in the region in the opening 44 of the single-crystal silicon layer 4 based on ion implantation using the mask material 43 as a mask. Additionally, at the same time, an impurity is also implanted into the single-crystal silicon layer 4 of the peripheral circuit unit to form the p-type well 12c that controls the threshold voltage of the peripheral transistor 14c by using this impurity. Then, the mask material 43 is removed.

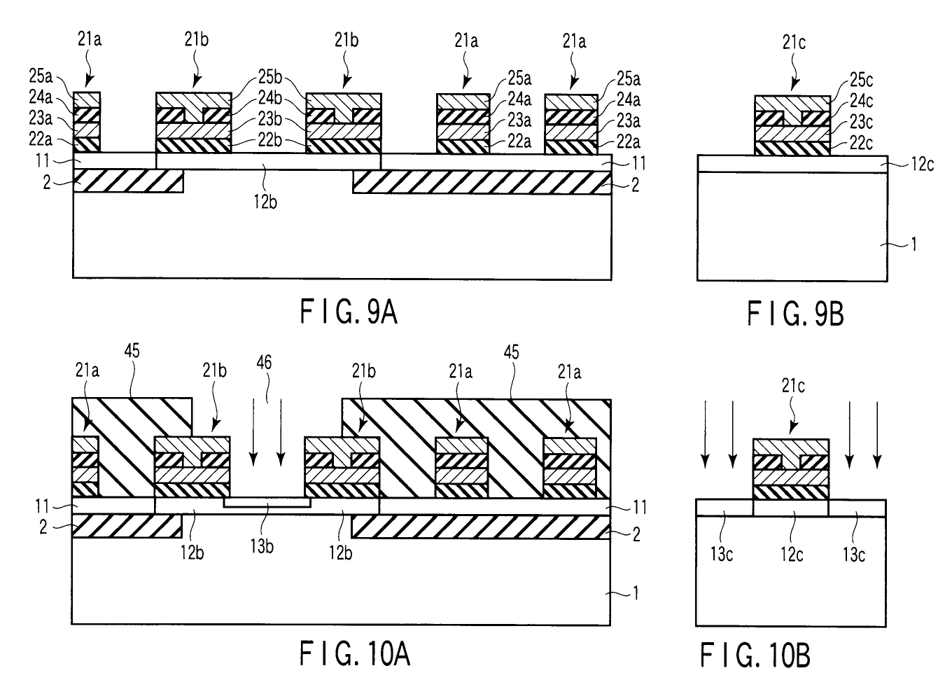

Subsequently, as shown in FIGS. 9A and 9B, the laminated gate structures 21a, 21b, and 21c are formed on the single-crystal silicon layer 4 based on, e.g., CVD, the lithograph process, or RIE. The laminated gate structure 21c is formed above the p-type well 12c, the laminated gate structure 21b is formed above the p-type well 12b, and the laminated gate structure 21a is formed above the buried insulating layer 2.

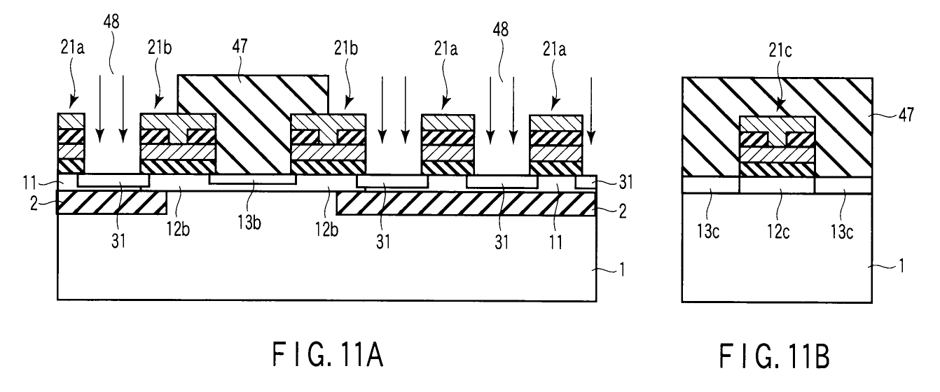

Then, as shown in FIGS. 11A and 10B, a mask material 45 having an opening 46 is formed on an entire surface of a structure obtained by the above-explained manufacturing steps based on, e.g., CVD, the lithography process, or RIE. The mask material 45 is formed to expose the p-type well 12b between the laminated gate structures 21b adjacent to each other and also formed to expose the p-type well 12c placed on both sides of the peripheral transistor 14c. Subsequently, the n-type diffusion layers 13b and 13c are formed in the p-type wells 12b and 12c based on ion implantation using the mask material 45 as a mask, respectively. Then, the mask material 45 is removed.

Subsequently, as shown in FIGS. 11A and 11B, a mask material 47 having an opening 48 is formed on an entire structure of a structure obtained by the above-explained manufacturing steps based on, e.g., CVD, the lithography process, or RIE. The mask material 47 is formed to expose the n⁻-type diffusion layer 11 between the laminated gate structures 21a and the n⁻-type diffusion layer 11 between the laminated gate structure 21a and the laminated gate structure 21b. Then, when an impurity is implanted by using the mask material 47 as a mask, each n⁺-type diffusion layer 31 is formed in a surface portion of the n⁻-type diffusion layer 11. Subsequently, the mask material 47 is removed.

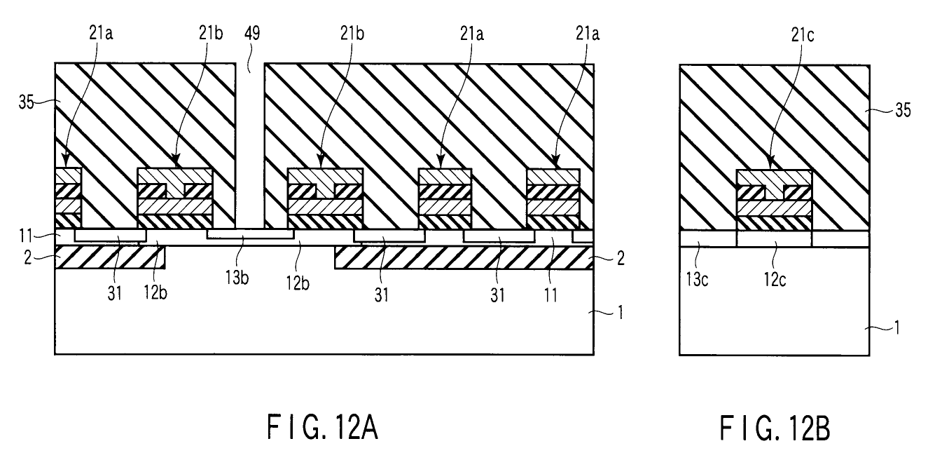

Then, as shown in FIGS. 12A and 12B, the interlayer insulating film 35 is formed on an entire structure obtained by the above-explained manufacturing steps based on, e.g., CVD. Subsequently, a contact hole 49 for the contact plug 33 is formed in the interlayer insulating film 35 by the lithography process. The contact hole 49 is formed to reach the surface of the n-type diffusion layer 13b.

Since the buried insulating layer 2 is not provided below a region where the contact hole 49 is to be formed, the following advantages can be obtained. That is, in a case where the buried insulating layer is provided, when the contact hole reaches the buried insulating layer due to overetching, a region where the contact plug is in contact with the single-crystal silicon layer (the silicon substrate) is a side surface of the contact plug alone. As a result, an area where the contact plug is in contact with the silicon substrate is considerably reduced, and a resistance value of this portion is increased. On the other hand, according to the present invention, even if the contact hole 49 reaches a position below the single-crystal silicon layer 4 due to overetching, a lower surface of the contact plug 33 can be guaranteed to come into contact with the single-crystal silicon layer 4 (the silicon substrate 1). Therefore, even if overetching occurs, the area where the contact plug 33 is in contact with the single-crystal silicon layer 4 (the silicon substrate 1) can be prevented from being reduced.

Then, when the contact plug 33 and the interconnect 34 are formed based on, e.g., CVD, the lithography process, or RIE, the semiconductor memory device having the structure depicted in FIGS. 2A and 2B can be obtained.

According to the semiconductor memory device conforming to the first embodiment of the present invention, each memory cell transistor 14a is formed in the SOI region, and each selective gate transistor 14b is formed in such a manner that its laminated gate structure 21b as a gate electrode spans the SOI region and the non-SOI region. That is, this transistor is formed in such a manner that a part of the laminated gate structure 21b is placed in the non-SOI region. Therefore, a parasitic capacitance reduction effect based on SOI technology can be obtained in the memory cell transistor 14a, and the selective gate transistor 14b can be equivalent to a counterpart formed on a bulk substrate. Therefore, the selective gate transistor 14b can be fabricated by the process common to the peripheral transistor 14c formed on the bulk substrate, thereby suppressing the number of manufacturing steps.

Further, according to the semiconductor memory device conforming to the first embodiment of the present invention, the buried insulating layer 2 on the silicon substrate 1 is partially widely removed to form the opening 3, and the single-crystal silicon layer 4 that grows with the silicon substrate 1 in this opening 3 as a seed is formed on the silicon substrate 1. Therefore, it is possible to easily realize a structure where each memory cell transistor 14a is formed in the SOI region and the gate electrode of each selective gate transistor 14b is partially formed in the non-SOI region. It is to be noted that the SOI substrate that realizes this structure can be fabricated at low cost.

Furthermore, according to the semiconductor memory device conforming to the first embodiment of the present invention, the shallow n⁺-type diffusion layer 31 with a high concentration is formed in the single-crystal silicon layer 4 between the memory cell transistors 14a. Therefore, a large current flowing through each memory cell transistor 14a can be assured, thus improving the read margin of the semiconductor memory device. Moreover, giving a gradient of an impurity concentration that the concentration is lowered along the depth direction of the single-crystal silicon layer 4 in the channel region of each memory cell transistor 14a enables improving cutoff characteristics.

It is to be noted that the example where each memory cell transistor 14a is formed on the n-type conductivity single-crystal silicon layer 4 has been explained in the foregoing embodiment. The present invention is not restricted thereto, and a p-type conductivity single-crystal silicon layer 4 may be adopted.

Additionally, the present invention can be also applied to other semiconductor memory devices such as an NOR flash memory device or an MONOS flash memory device that uses a silicon nitride film as an electric charge storage layer in place of a floating gate electrode.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a silicon substrate including a first region which has a buried insulating layer below a single-crystal silicon layer and a second region which does not have the buried insulating layer below the single-crystal silicon layer;
at least one memory cell transistor which has a first gate electrode, the first gate electrode being provided on the single-crystal silicon layer in the first region; and
at least one selective gate transistor which has a second gate electrode, the second gate electrode being provided to be partially placed on the single-crystal silicon layer in the second region.

2. The device according to claim 1, wherein the buried insulating layer has an opening associated with the second region, and the single-crystal silicon layer is formed based on growth using the silicon substrate exposed in the opening as a seed.

3. The device according to claim 1, wherein an impurity region is provided in the single-crystal silicon layer in the first region below the first gate electrode, and the impurity region has an impurity concentration increased on the first gate electrode side and reduced on the buried insulating layer side.

4. The device according to claim 1, further comprising one contact plug which is adjacent to the second gate electrode of the one selective gate transistor and formed on the single-crystal silicon layer in the second region.

5. The device according to claim 4, wherein the one contact plug is connected with the second gate electrode through a first diffusion layer which is formed in the single-crystal silicon layer in the second region, is of a first conductivity type, and has a first concentration.

6. The device according to claim 1, wherein the first gate electrode and the second gate electrode are connected with each other through a second diffusion layer which is formed in the single-crystal silicon layer in the first region, is of a first conductivity type, and has a second concentration.

7. The device according to claim 3, wherein the impurity region is of a first conductivity type and has a third concentration.

8. The device according to claim 1, further comprising one contact plug which is adjacent to the second gate electrode of the one selective gate transistor and formed on the single-crystal silicon layer in the second region,
wherein the first contact plug is connected with the second gate electrode through a first diffusion layer which is formed in the single-crystal silicon layer in the second region, is of a first conductivity type, and has a first concentration,
the first gate electrode and the second gate electrode are connected with each other through a second diffusion layer which is formed in the single-crystal silicon layer in the first region, is of the same conductivity type as the first conductivity type, and has a second concentration higher than the first concentration, and
an impurity region which is of the same conductivity type as the first conductivity type and has a third concentration lower than the first concentration is formed in the single-crystal silicon layer in the first region below the first gate electrode excluding the second diffusion layer.

9. The device according to claim 8, wherein the impurity region has an impurity concentration increased on the first gate electrode side.

10. A semiconductor memory device comprising:
a silicon substrate including a first region which has a buried insulating layer below a single-crystal silicon layer and a second region which is adjacent to the first region and does not have the buried insulating layer below the single-crystal silicon layer;
at least one memory cell transistor having a first gate electrode formed on the single-crystal silicon layer in the first region;
one selective gate transistor having a second gate electrode which is adjacent to the one memory cell transistor and formed on the single-crystal silicon layer to span the first region and the second region; and
one contact plug which is adjacent to the one selective gate transistor and formed on the single-crystal silicon layer in the second region,
wherein the one contact plug and the second gate electrode are connected with each other through a first diffusion layer which is formed in the single-crystal silicon layer in the second region, is of a first conductivity type, and has a first concentration,
the first gate electrode and the second gate electrode are connected with each other through a second diffusion layer which is formed in the single-crystal silicon layer in the first region, is of the same conductivity type as the first conductivity type, and has a second concentration higher than the first concentration, and
an impurity region which is of the same conductivity type as the first conductivity type and has a third concentration lower than the first concentration is formed in the single-crystal silicon layer in the first region below the first gate electrode excluding the second diffusion layer.

11. The device according to claim 10, wherein the buried insulating layer has an opening associated with the second region, and the single-crystal silicon layer is formed based on growth using the silicon substrate exposed in the opening as a seed.

12. The device according to claim 10, wherein the impurity region has an impurity concentration which is increased on the first gate electrode side and reduced on the buried insulating layer side.

13. A manufacturing method of a semiconductor memory device having a memory cell unit, comprising:
forming an insulating layer on a silicon substrate, the insulating layer having an opening from which a part of a surface of the silicon substrate associated with the memory cell unit is exposed;
forming a semiconductor layer on the surface of the silicon substrate in the opening and on the insulating layer;
forming a first impurity region which is of a first conductivity type in a first region of the semiconductor layer associated with the insulating layer;
forming a first impurity region which is of a second conductivity type in a second region of the semiconductor layer associated with the opening;
forming at least one first gate structure which is associated with the first region and has a first insulating film, a first electrode, a second insulating film, and a second electrode laminated on the semiconductor layer and one second gate electrode which has a third insulating film and a third electrode laminated on the semiconductor layer to span the first region and the second region;
forming a second impurity region which is of the first conductivity type in a surface portion of the semiconductor layer associated with the second region to be adjacent to the one second gate structure; and
forming a third impurity region which is of the first conductivity type in a surface portion of the semiconductor layer associated with the first region to be adjacent to the one first gate structure.

14. The method according to claim 13, wherein the semiconductor layer is a single-crystal silicon layer and formed based on growth using the silicon substrate exposed in the opening as a seed.

15. The method according to claim 14, wherein the single-crystal silicon layer is formed by annealing amorphous silicon or polysilicon.

16. The method according to claim 13, wherein the first impurity region which is of the first conductivity type has an impurity concentration that is increased on the first gate electrode side and reduced on the buried insulating layer side.

17. The method according to claim 13, wherein forming the one first gate electrode and the third impurity region which is of the first conductivity type is forming a depletion-type memory cell transistor, and forming the one second gate structure and the second impurity region which is of the first conductivity type is forming an enhancement-type selective gate transistor.

18. The method according to claim 13, further comprising forming one contact plug that is connected with the second impurity region which is of the first conductivity type to be adjacent to the one second gate structure.

19. The method according to claim 13, wherein a peripheral circuit unit is further provided on the silicon substrate, and at least one peripheral transistor which is of an enhancement type is formed in the peripheral circuit unit.

20. The method according to claim 19, wherein the one peripheral transistor includes:
forming a semiconductor layer on the silicon substrate associated with the peripheral circuit unit;
forming a second impurity region which is of the second conductivity type in the semiconductor layer associated with the peripheral circuit unit;
forming at least one third gate structure having a fourth insulating film and a fourth electrode laminated on the second impurity region which is of the second conductivity type; and
forming a fourth impurity region which is of the first conductivity type in the semiconductor layer to be adjacent to the one third gate structure.
